(19) United States
(12) Patent Application Publication
(10) Pub. No.: US 2025/0380389 A1
(43) Pub. Date: Dec. 11, 2025

(54) VARIABLE-AIRFLOW INLET BARRIER FOR INFORMATION TECHNOLOGY EQUIPMENT

(71) Applicant: INTERNATIONAL BUSINESS MACHINES CORPORATION, ARMONK, NY (US)

(72) Inventors: Blake Overton, Olivebridge, NY (US); Khaalid Persaud Juggan McMillan, Haverstraw, NY (US); John S. Werner, Fishkill, NY (US); Arkadiy O. Tsfasman, Wappingers Falls, NY (US)

(21) Appl. No.: 18/735,236

(22) Filed: Jun. 6, 2024

(51) Int. Cl. H05K 7/20

(52) U.S. Cl. CPC H05K 7/20836; H05K 7/20718

(57) ABSTRACT

According to one embodiment, a method, computer system, and computer program product for dynamically cooling and protecting components of a computing system using a dynamic barrier system is provided. The present invention may include extracting a physical configuration of a computing system and a dynamic barrier system; monitoring, in real time, component data of components comprising the computing system; recording, by sensors, environmental data of the computing system; responsive to determining that an affected component of the components has exceeded a temperature threshold, identifying aligned apertures of the adjustable apertures based on the physical configuration; calculating percentage open values for the adjustable apertures and the aligned apertures based on the environmental data and the component data; and setting the adjustable apertures and the aligned apertures to the calculated percentage open values.

### BACKGROUND

The present invention relates, generally, to the field of computing, and more particularly to datacenter heat management.

Modern life is overwhelmingly defined and dominated by the creation, transmission, and exchange of digital information. Increasingly complex and extensive physical infrastructure, including computers, digital storage devices, networks, and other such information technology equipment, are continually deployed to facilitate the creation, processing, storage, security, and transmission of increasing amounts of electronic data. Storage of such electronic data has become more and more centralized in dedicated storage facilities, called datacenters, as such facilities realize increasing efficiencies in storing the sheer volume of electronic data, and as individuals and enterprises turn to cloud storage solutions for managing their data. However, a significant concern in deploying and maintaining such centralized physical infrastructure is the management of heat; information technology equipment generates heat, and as datacenters grow in size and number, the management of such heat likewise grows in importance.

Information technology equipment performs most efficiently in cooler environments and suffers degraded performance and even damage when exposed to sufficiently high temperatures. The field of datacenter heat management may be the technological field concerned with developing and deploying hardware and software methods to facilitate the movement of heat away from information technology equipment.

### SUMMARY

According to one embodiment, a method, computer system, and computer program product for dynamically cooling and protecting components of a computing system using a dynamic barrier system is provided. The present invention may include a method, computer system, and computer program product for dynamically cooling and protecting components of a computing system using a dynamic barrier system. The present invention may include extracting a physical configuration of a computing system and a dynamic barrier system; monitoring, in real time, component data of components comprising the computing system; recording, by sensors, environmental data of the computing system; responsive to determining that an affected component of the components has exceeded a temperature threshold, identifying aligned apertures of the adjustable apertures based on the physical configuration; calculating percentage open values for the adjustable apertures and the aligned apertures based on the environmental data and the component data; and setting the adjustable apertures and the aligned apertures to the calculated percentage open values.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment;

FIG. 2 illustrates an exemplary dynamic cooling system according to at least one embodiment;

FIG. 3 is an operational flowchart illustrating a dynamic cooling process according to at least one embodiment;

FIG. 4 illustrates an exemplary dynamic barrier system according to at least one embodiment;

FIG. 5 illustrates an exemplary default state of the dynamic barrier system according to at least one embodiment; and

FIG. 6 illustrates an exemplary adjusted state of the dynamic barrier system according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

Embodiments of the present invention relate to the field of computing, and more particularly to datacenter heat management. The following described exemplary embodiments provide a system, method, and program product to, among other things, dynamically adjust adjustable apertures to change an inlet airflow gradient across the adjustable apertures based on the current workload and/or power consumption of a computing system.

As previously described, the field of datacenter heat management may be the technological field concerned with developing and deploying hardware and software methods to facilitate the movement of heat away from information technology equipment. Systems for cooling datacenters generally fall into two broad categories, liquid-cooled systems and air-cooled systems, which both use fluid as a medium to move heat away from information technology equipment. Liquid-cooled systems typically use a liquid coolant to remove heat directly from the chips comprising the information technology equipment, which is referred to as chip-level cooling; liquid-cooled systems typically cannot scale beyond chip-level cooling. Air-cooled systems force hot air containing the thermal load from the server racks across a refrigerant coil; the thermal load is absorbed into the refrigerant and is then vented away in an airstream or imparted into a fluid such as water or glycol. Air-cooled systems may vary in scale from server-level to row-level/rack-level to room-level cooling.

In many current air-cooled systems, static barriers are typically installed in front of IT equipment, for example to protect the sensitive internals of IT equipment from dust, accidental contact with human administrators or other equipment, et cetera. These static barriers may include, for instance, doors on server racks, bezels on IT equipment, et cetera. In some air-cooled systems, forced air may be directed at, towards, or around the enclosure to provide cooling. For example, in raised floor data centers, airflow may be provided through perforated tiles set in the floor below the IT equipment. However, forced air cannot be directed evenly across an entire static barrier, so there are inevitably regions of the static barrier, for example those in front of vents or fans, where airflow is greater, and regions where airflow is lesser. This arrangement can create an airflow gradient over the static barrier, where colder air is present where forced air is directed against the static barrier, and hotter air is present at the regions of the static barrier where the airflow from forced air is lesser. Separately, thermodynamic properties such as the natural tendency of heat to rise can affect temperature and airflow in and around the IT equipment, causing, for example, components at the top of the static barrier to be cooled less efficiently than components at the bottom of the static barrier. These two factors conspire to cause uneven cooling of the IT equipment, resulting in a temperature gradient across the face of the static barrier and over the IT devices.

Furthermore, many current air-cooled systems do not allow for system-level airflow regulation, and are therefore unable to alter airflow to the IT equipment to respond to localized changes in air temperature, such as might result from the natural tendency of heat to rise, or from heat emitted from components, for example due to a malfunction or changes in the workload imposed on individual components. Additionally, many air-cooled systems do not automatically detect emergencies such as fires or malfunctions and operate adjustable apertures to close off and isolate such emergencies to the racks where they occur. As a result, natural thermodynamic processes, fires, malfunctions, excessive workloads, et cetera both in the system or in neighboring systems may cause hot spots affecting the system that the system cannot identify or address, which may affect the performance and longevity of the IT equipment. In more serious cases, such excessive temperature spikes may cause failure in devices such as storage drives, motherboards, and power supplies, and may cause CPUs to melt and cease functioning; the loss of a CPU may in turn increase the workload on other CPUs in the system and may cause their temperatures to increase, potentially resulting in a chain reaction of overheating.

Additionally, current air-cooled methods do not leverage the idea that methods and devices for controlling airflow to IT devices in an air-cooled system may additionally be employed to control the flow of acoustic and electromagnetic waves within the datacenter to add extra functionality to the air-cooling system. Current methods fail to utilize louvres and other such adjustable apertures on the static barrier to dampen the amount of sound produced by a server rack. Additionally, current methods fail to employ such adjustable apertures to dampen electromagnetic waves produced by IT equipment in the server rack or to reduce the electromagnetic waves entering the server rack, based on electromagnetic sensor readings and the electromagnetic compatibility of devices inside and/or outside of the server rack.

As such, it may be advantageous to, among other things, implement a system that utilizes adjustable apertures to dynamically adjust to even out gradients in airflow affecting the server rack, account for changes in temperature caused by internal workload and natural thermodynamic effects, account for local changes in temperature caused by internal or external workloads or emergencies, selectively dampen sound, and adjust exposure of components to electromagnetic interference. Therefore, the present embodiment has the capacity to improve the technical field of datacenter heat management by providing a method that provides improved granularity in its operation over current methods, resulting in improved detection and amelioration of hot spots and other local changes in temperature within datacenters due to factors such as malfunction, emergency, workload, and airflow, resulting in improved efficiency, longevity, and performance of IT equipment, and preventing premature failure and damage due to overheating. In other words, such a system would improve sustainability of a computing system by reducing operational stress on the components, allowing components to last longer and potentially be reused. Furthermore, such a system would enable rapid responsiveness in certification testing without part re-design. Embodiments of the present invention further stand to provide the advantage of enabling the air-cooling system to protect sensitive equipment in the computing system from interference or damage from electromagnetic radiation, and to protect human users from volume-related discomfort or injury by dampening sound produced by the IT equipment.

According to one embodiment, the invention is a processor-implemented method for dynamically cooling and protecting components of a computing system using a dynamic barrier system, the method comprising: extracting a physical configuration of the computing system and the dynamic barrier system; monitoring, in real time, component data of one or more components comprising the computing system; recording, by one or more sensors, environmental data of the computing system; responsive to determining that an affected component of the one or more components has exceeded a temperature threshold, identifying one or more aligned apertures of one or more adjustable apertures based on the physical configuration; calculating one or more percentage open values for the one or more adjustable apertures and the one or more aligned apertures based on the environmental data and the component data; and setting the one or more adjustable apertures and the one or more aligned apertures to the calculated one or more percentage open values. Such embodiments enable the dynamic barrier system to swiftly cool components that have exceeded efficient operating temperatures and/or safe operating temperatures, and thereby restore efficient or safe operation by swiftly increasing airflow through the computing system to the affected components.

According to an embodiment, the invention further comprises identifying one or more adjacent apertures to the one or more aligned apertures, and where the calculating further comprises calculating percentage open values for the aligned apertures. Such embodiments enable the dynamic barrier system to use the adjustable apertures around the aligned apertures to direct airflow towards the affected components, improving the cooling speed and efficiency.

The invention may further comprise embodiments where the components comprise at least one electromagnetically sensitive component, and the calculating is based on one or more readings by an electromagnetic interference sensor of the one or more sensors. Such embodiments allow the dynamic barrier system to adjust the exposure of such sensitive components to electromagnetic interference, and thereby protect them from disruptive or damaging levels of electromagnetic interference while still providing airflow. Such embodiments could allow for rapid responsiveness in certification testing scenarios where electromagnetic interference is critical to operations.

The invention may further comprise embodiments where the calculating is based on a temperature gradient or an airflow gradient. Such embodiments allow the dynamic barrier system to dynamically adjust to counteract the uneven cooling effects of natural thermodynamic processes, which naturally result in temperature increases from the bottom of an enclosure to the top of an enclosure; additionally, such embodiments allow the dynamic barrier system to dynamically adjust to counteract the uneven cooling effects of non-uniform airflow over the computing system caused, for example, by vents or nozzles directing air unevenly against the computing system.

According to an embodiment, the invention further comprises, responsive to detecting a human, reducing the percentage open values for the one or more adjustable apertures to reduce a produced sound below a sound threshold. Such embodiments enable the dynamic barrier system to dampen acoustic noise to meet Occupational Safety and Health Administration (OSHA) or other acoustic safety requirements and prevent sound-related injury to human personnel.

According to an embodiment, the invention further comprises, responsive to determining that a temperature measurement exceeds a fire emergency threshold, closing the adjustable apertures. Such embodiments enable the dynamic barrier system to close off and physically isolate the computing system from other systems when a fire or malfunction is detected, providing a barrier to mitigate damage to neighboring systems from a fire or malfunction occurring within the computing system, or to help protect the computing system from a fire or malfunction occurring in adjacent computing systems.

The invention may further comprise embodiments where the calculating is performed using a machine learning model. Such embodiments allow the system to utilize feedback to further improve the calculation of percentage open values based on patterns, improving the accuracy of percentage open value calculation, and improving the cooling ability of the system.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating, or semiconductor layers at the interface of the two elements.

In the interest of not obscuring the presentation of the embodiments of the present invention, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The following described exemplary embodiments provide a system, method, and program product to dynamically adjust adjustable apertures to change an inlet airflow gradient across the adjustable apertures based on the current workload and/or power consumption of a computing system.

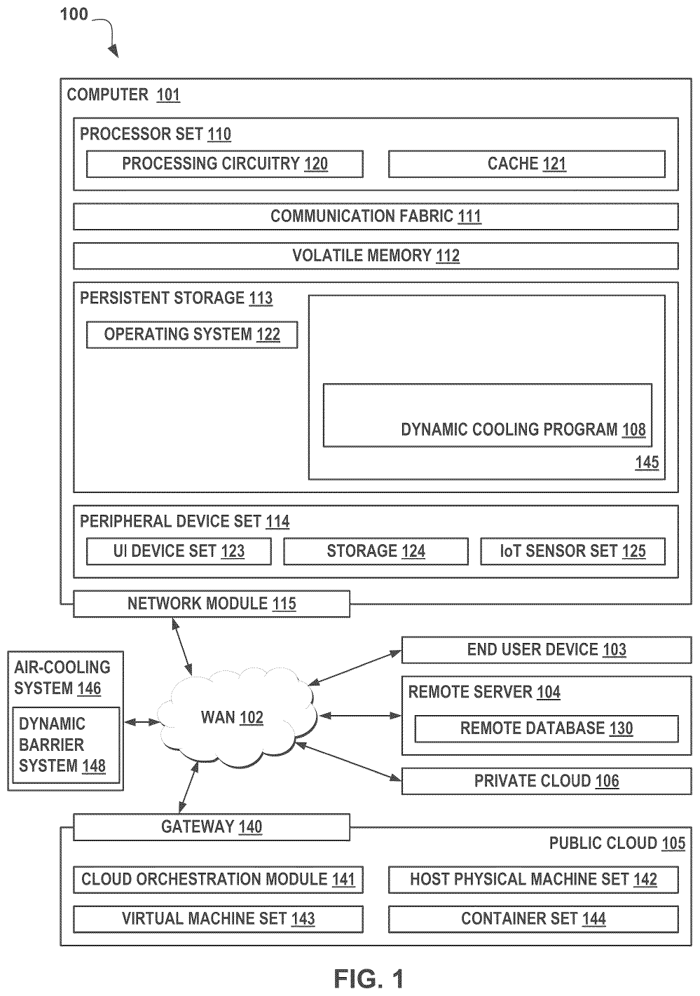

Referring now to FIG. 1, computing environment 100 contains an example of an environment for the execution of at least some of the computer code involved in performing the inventive methods, such as code block 145, which may comprise dynamic cooling program 108. In addition to code block 145, computing environment 100 includes, for example, computer 101, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and code block 145, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in code block 145 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in code block 145 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is a cloud server designed to store data for an end user and provide stored data to the end user upon request, provided data would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to the present embodiment, the dynamic cooling program 108 may be a program enabled to dynamically adjust adjustable apertures to change an inlet airflow gradient across the adjustable apertures based on the current workload and/or power consumption of a computing system. The dynamic cooling program 108 may, when executed, cause the computing environment 100 to carry out a dynamic cooling process 300. The dynamic cooling process 300 may be explained in further detail below with respect to FIG. 3. In embodiments of the invention, the dynamic cooling program 108 may be stored and/or run within or by any number or combination of devices including computer 101, EUD 103, remote server 104, private cloud 106, and/or public cloud 105, peripheral device set 114, and gateway 140 and/or on any other device connected to WAN 102. Furthermore, the dynamic cooling program 108 may be distributed in its operation over any number or combination of the aforementioned devices.

According to the present embodiment, the air-cooling system 146 is the collection of devices, computer software, hardware, and firmware that is configured to cool the IT equipment of a computing system. The air-cooling system 146 may comprise a number of fans, vents, ducts, and other devices or structures for continually moving air through the datacenter and past the IT equipment, using air as a medium to conduct the thermal load generated by the IT equipment away from the IT equipment. Air carrying the thermal load is then forced across a fluid coil filled with some type of coolant, such as chilled water, glycol, refrigerant, et cetera; the thermal load is absorbed into the coolant and is then vented out of the computing system in an airstream or imparted into a fluid such as water or glycol to be transported out of the datacenter. The air-cooling system 146 may make use of a raised floor design where a platform, or raised floor, is constructed over the actual floor of the room, creating a cavity between the actual floor and the raised floor where air can flow. The IT equipment is placed on the raised floor, which may be vented near the IT equipment or may be permeable throughout, allowing air to flow past the IT equipment. The raised floor design can help compensate for stratification and improve the distribution and flow of conditioned air.

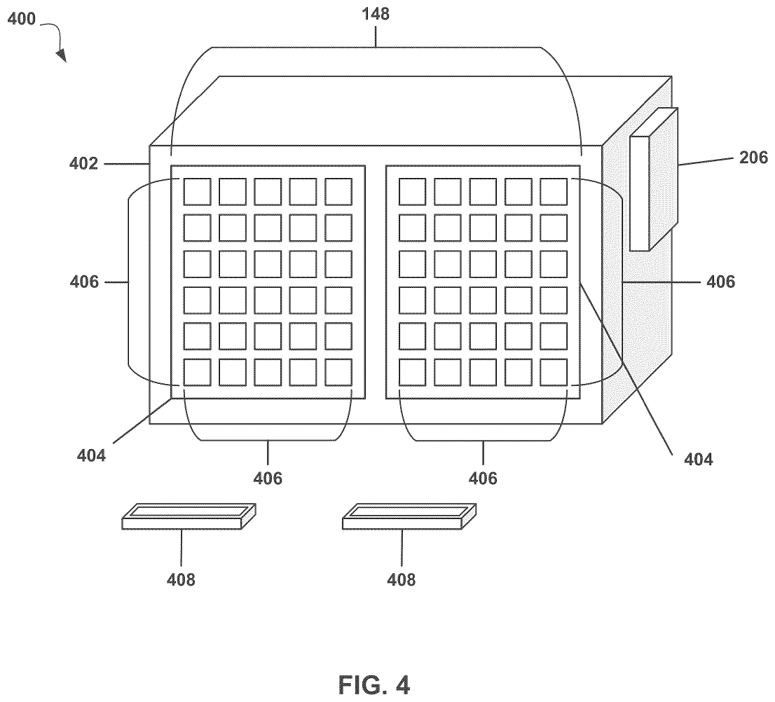

According to the present embodiment, the dynamic barrier system 148 may be a collection of devices, computer software, hardware, and firmware which together operate to dynamically adjust adjustable apertures to change an inlet airflow gradient across the adjustable apertures based on the current workload and/or power consumption of a computing system. The dynamic barrier system 148 may be one or more static barriers, which may be integrated into or comprise a physical enclosure that holds components of a computer system. The static barriers may be, for example, doors on server racks, bezels on IT equipment, et cetera. The static barriers may comprise one or more adjustable apertures, which may be openings in the static barrier each equipped with a cover. The cover may be any moveable barrier capable of covering the adjustable aperture to fully block airflow when in a closed state, and providing unimpeded airflow through the adjustable aperture when in an open state; the cover may further be actuated by a remote signal to move the cover between the open state and the closed state, and to stop the cover at any of multiple points between the open and closed states such that airflow through the adjustable aperture may be partially restricted. The cover may be a rigid panel capable of swinging or sliding across the aperture, may comprise multiple rigid panels to form, for instance, a louvre, may be a non-rigid geometric membrane, et cetera. The cover may be equipped with a means of moving the cover between the open and closed states, such as a motor. The adjustable aperture may be equipped with one or more environmental sensors such as pressure sensors or thermal sensors to detect temperature and airflow through the adjustable aperture. The dynamic barrier system 148 may be a component of and/or otherwise integrated into the air-cooling system 146, or may be a separate, independent system. The dynamic barrier system 146 may be explained in further detail below with respect to FIG. 4. The dynamic barrier system 146 may, when operated by dynamic cooling program 108, carry out the dynamic cooling process 300. The dynamic cooling process 300 may be explained in further detail below with respect to FIG. 3. In embodiments of the invention, for example where one or more of the components of the computing system 202 are sensitive to electromagnetic interference, the enclosure and/or the cover may be electromagnetically shielded, so as to protect the one or more sensitive components within.

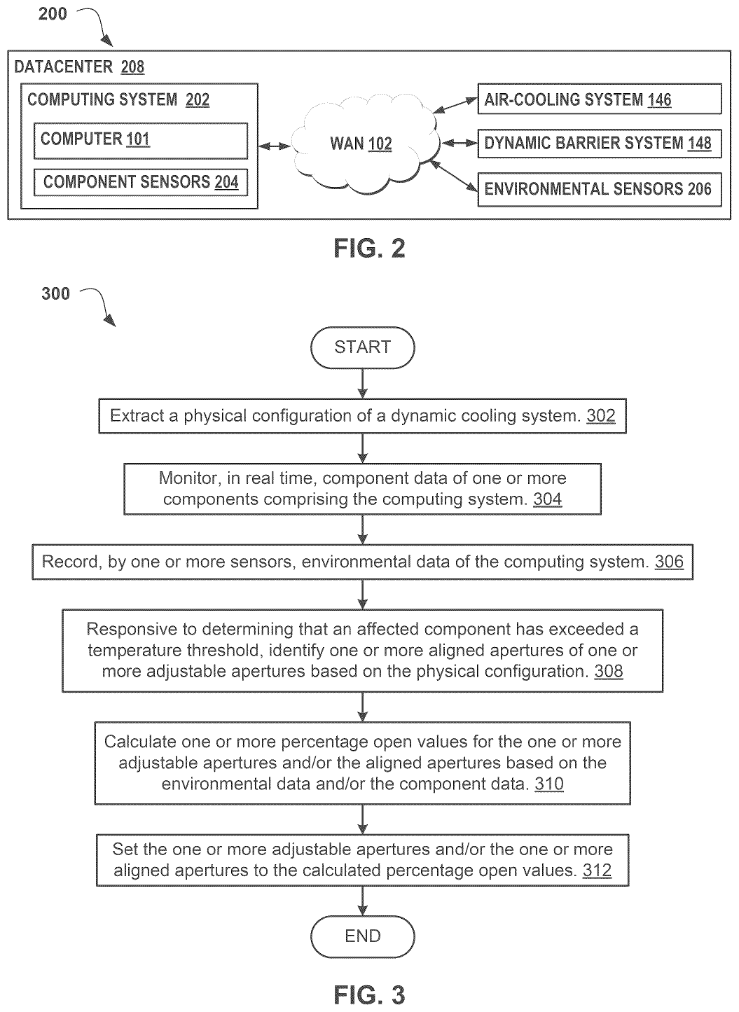

Referring now to FIG. 2, an exemplary dynamic cooling system 200 is depicted, according to at least one embodiment. The dynamic cooling system 200 may comprise a computing system 202, which in turn may comprise one or more computers 101 and one or more component sensors 204, an air-cooling system 146, a dynamic barrier system 148, and one or more environmental sensors 206, all disposed within a datacenter 208. The computing system 202 may be a collection of integrated devices, computer software, hardware, and firmware that store, process, input, and output data and information. The computing system 202 may be designed to perform any number or combination of purposes, such as data storage, high-speed computing, networking, ct cetera. The computing system 202 may range in scale from a single server, computer, or other device to an integrated group of multiple servers, computers, or other devices. For example, the computing system 202 may be a single server rack that contains multiple separate x86 servers. In embodiments, the hardware components of the computing system 202 may all be located in the same geographic area, such as within datacenter 208, such that they may all be cooled by the air-cooling system 146. The hardware components of the computing system 202 may be disposed within one or more enclosures, wherein the dynamic barrier system 146 is integrated into the enclosures. The enclosures may be physical structures designed to hold the hardware components and protect them from damage. The enclosures may be server racks, computer cases, cabinets, towers, chassis, et cetera. In embodiments, devices comprising the air-cooling system 146, such as fans, may be integrated into the enclosures. The dynamic cooling program 108 may or may not be present within computing system 202. The computing system 202, the air-cooling system 146, the dynamic barrier system 148, and the environmental sensors 206 may all be interconnected via WAN 102, through which they may communicate with each other.

The component sensors 204 may be any number or combination of devices designed to record data regarding the components of the computing system 202 and communicate that data to the dynamic cooling program 108. For example, the component sensors 204 may be thermal sensors such as thermistors or thermometers mounted on individual components to monitor the temperature of that component or mounted on the inside of the enclosure to monitor the general interior temperature of the enclosure or temperature at particular points, et cetera. In embodiments, the component sensors 204 may be power consumption sensors such as current transformers for measuring the power consumption of the computing system 202 and/or individual components, ct cetera. The component sensors 204 may be mounted within the one or more enclosures and may be part of the IoT sensor set 125.

The environmental sensors 206 may be devices designed to measure environmental conditions around the one or more enclosures holding the computing system 202 that the dynamic cooling program 108 may use to operate the dynamic barrier system 148. In embodiments, the environmental sensors 206 may comprise temperature sensors and/or pressure sensors mounted in some or all of the adjustable apertures comprising the dynamic barrier system 148 to enable accurate measurement of temperature and/or pressure at the adjustable apertures. In embodiments, the environmental sensors 206 may include cameras or proximity sensors capable of recording data that the dynamic cooling program 108 can use to detect the presence of humans near the one or more enclosures, such as motion, images, et cetera. In embodiments, for example where one or more sub-components of the computing system 202 comprise sensitive electronic equipment that is vulnerable to electromagnetic interference, the environmental sensors 206 may include electromagnetic sensors capable of measuring electromagnetic interference in the environment around the enclosure containing the sensitive sub-component.

Referring now to FIG. 3, an operational flowchart illustrating a dynamic cooling process 300 is depicted according to at least one embodiment. At 302, the dynamic cooling program 108 may extract a physical configuration of a dynamic cooling system 200. Here, the dynamic cooling program 108 may receive one or more configuration files or maps that identify the components of the computing system 202 and detail the physical arrangement and spatial configuration of components and structures comprising the computing system 202 and the dynamic barrier system 148, such that the dynamic cooling program 108 may be able to infer the distances between the components of computing system 202 and the closest adjustable apertures 406 in the dynamic barrier system 148. In embodiments, the dynamic cooling program 108 may further extract the physical arrangement and spatial configuration of devices and structures comprising the air-cooling system 146. In embodiments, the dynamic cooling program 108 may further extract the locations of the component sensors 204 and the environmental sensors 206, and/or the layout of datacenter 208.

In some embodiments of the invention, the dynamic cooling program 108 may extract device information regarding components of the computing system 202, such as the thermal load generated by the component during use under certain workloads, the power utilization of the component, the thermal load generated under normal operating conditions, the thermal load generated under certain workloads, et cetera. In embodiments, the device information may include whether a component is “sensitive,” where sensitive components possess an electromagnetic compatibility value falling below a susceptibility threshold, where the susceptibility threshold represents an electromagnetic compatibility below which the component is likely to malfunction or experience errors. The electromagnetic compatibility, and/or sensitive component status, of one or more components of the computing system 202 may be pre-provided to the dynamic cooling program 108, or dynamic cooling program 108 may retrieve data regarding the electromagnetic compatibility and/or sensitive status from, for example, a hardware specification database or some other digital resource. Sensitive components may include such devices as application-specific integrated circuits (ASIC), field-programmable gate arrays (FPGA), high-speed signal lines, or any other hardware devices for which ordinary levels of electromagnetic interference within a datacenter can alter the integrity of signals within the component such that information within and/or sent between the components is degraded, impairing the operation of the components and/or the accuracy of the information beyond error correction capabilities.

At 304, the dynamic cooling program 108 may monitor, in real time, component data of one or more components comprising the computing system. The component data may be data regarding the power utilization of each component comprising the computing system 202. Component data may be recorded by component sensors 204 such as voltmeters, current transformers, et cetera, and/or may be retrieved by dynamic cooling program 108. In an example, component-sensor-equipped devices such as power management integrated circuits or voltage regulators may register power utilization of computing system 202 components through their firmware and/or report power utilization to a controlling entity such as a hardware management console, central controller, power distribution unit, et cetera; the dynamic cooling program 108 may query the component-sensor-equipped components and/or controlling entities of computing system 202 to acquire data regarding the power consumption of individual components of computing system 202. In embodiments, for example where the dynamic cooling program 108 considers factors instead of or in addition to power consumption, the component data may additionally or alternatively include internal component temperature, workload, and/or ambient temperature. The component sensors 204 may record internal and/or ambient temperature data, where internal temperature may comprise temperature within the enclosure and/or immediately surrounding a given component, and where ambient temperature data may be a temperature of air outside of but local to the enclosure, for instance up to a meter's distance from the enclosure. In embodiments, the ambient temperature may be the environmental air temperature in the datacenter where computing system 202 is located. In embodiments, the dynamic cooling program 108 may query load balance clusters or schedulers to retrieve workloads allocated to components, for example by querying or consulting logging mechanisms inherent to the computing system 202 such as internal networking infrastructure including, for example, baseboard management controllers, et cetera.

At 306, the dynamic cooling program 108 may record, by one or more sensors 206, environmental data of the computing system. Here, the dynamic cooling program 108 may record environmental data using the one or more environmental sensors 206. In some embodiments, for example where the adjustable apertures of the dynamic barrier system 148 are equipped with temperature sensors, the dynamic cooling program 108 may record the temperature at each adjustable aperture. The dynamic cooling program 108 may create a thermal gradient which represents each temperature reading in relation to the location of the adjustable aperture where it was measured. In some embodiments, for example where the adjustable apertures of the dynamic barrier system 148 are equipped with pressure sensors, and/or where the cooling system utilizes forced air, the dynamic cooling program 108 may record the airflow at each adjustable aperture. The dynamic cooling program 108 may create an airflow gradient which represents each pressure reading in relation to the location of the adjustable aperture where it was measured to create a representation of the airflow through the adjustable apertures. In some embodiments, for example where dynamic cooling program 108 adjusts the adjustable apertures to muffle sound or to reduce electromagnetic interference, the dynamic cooling program 108 may record sound and electromagnetic interference from specially equipped environmental sensors 206.

At 308, the dynamic cooling program 108 may, responsive to determining that an affected sub-component has exceeded a temperature threshold, identify one or more adjacent adjustable apertures of one or more adjustable apertures based on the physical configuration. In embodiments, the dynamic cooling program 108 may determine a threshold value, or temperature threshold, for each component comprising the computing system 202, where the temperature threshold represents the maximum allowed operating temperature for that component. The temperature threshold may be determined separately for each component based on the operating statistics of the different components, which may be pre-provided to dynamic cooling program 108 or retrieved from an external database, service, repository, et cetera. In embodiments, the temperature threshold may be pre-provided to dynamic cooling program 108 by a human user, service, or other external source. The temperature threshold may be, for example, a safety temperature above which operation may result in damage to the component, an efficiency temperature, above which operation of the component may decrease in efficiency, and/or a longevity temperature, above which the longevity of the component may be decreased. Chip reliability is directly related to duration spent operating at high temperatures, while the lower the temperature, the more efficiently the chip operates; in embodiments, the temperature threshold may be a pre-selected temperature that balances cooling cost or power efficiency against longevity.

In embodiments of the invention, for example where the dynamic cooling program 108 monitors the power consumption of the components, the temperature threshold may further comprise a power consumption value that corresponds to the temperature represented by the temperature threshold. Because power consumption shares a predictable, quantifiable relationship with the thermal load that a given component generates over a given period of time based on the operating characteristics of that component, it is possible to calculate when the thermal load generated by a component has exceeded the temperature threshold for that component based on the component's power consumption. Each component may be associated with a history of temperature in relation to that component's power consumption, which the dynamic cooling program 108 may reference as long as the proper function is retained to extrapolate temperature from the component's power consumption. As such, the power consumption value represents a power utilization of the component above which the component will generate a thermal load in excess of the temperature threshold.

In embodiments, for example where the dynamic cooling program 108 monitors the workload of the components, the dynamic cooling program 108 may determine a workload value for each component comprising the computing system 202. The workload being performed by a component shares a predictable, quantifiable relationship with the power utilized by that component, which in turn, shares a predictable, quantifiable relationship with the thermal load that a given component generates based on the operating characteristics of that component. Workloads of a computing system 202 tend to utilize a combination of components consistently such as memory read/write, IO intensive, compute intensive, et cetera, and these workloads have their own unique patterns. It is, therefore, similarly possible to calculate when the thermal load generated by a component has exceeded the temperature threshold for that component based on the size of the component's workload and/or the overall workload allocated to computing system 202 over a period of time. As such, the threshold value represents an individual workload of the component or a general workload of the computing system 202 above which the component will generate a thermal load in excess of the specified operating temperatures.

The dynamic cooling program 108 may compare the power consumption for each component against the temperature threshold at regular intervals, for example on the order of seconds. In embodiments, for example where the dynamic cooling program 108 monitors the power consumption of the components, the dynamic cooling program 108 may compare the power consumption for each component against the power consumption value calculated to represent the temperature threshold. In embodiments, for example where the dynamic cooling program 108 monitors the workload of the components, the dynamic cooling program 108 may compare the workload for each component against the workload value calculated to represent the temperature threshold. In embodiments, for example where the dynamic cooling program 108 directly monitors the temperature of the components, for example using on-chip component sensors 204 or adjustable-aperture-mounted environmental sensors 406, the dynamic cooling program 108 may simply compare the measured temperature value against the temperature threshold, with no conversion necessary.

If, based on the comparison, the dynamic cooling program 108 determines that the component exceeds the temperature threshold or the equivalent power consumption value or workload value, the dynamic cooling program 108 may identify one or more adjacent adjustable apertures from among the adjustable apertures comprising the dynamic barrier system 148. Adjacent adjustable apertures may be adjustable apertures that are physically closest to the affected component, or the component that has exceeded its temperature threshold. The dynamic cooling program 108 may consult the extracted physical configuration of the computing system 202 and the dynamic barrier system 148 to determine the distances between the affected component and all adjustable apertures. The dynamic cooling program 108 may select the adjustable aperture with the shortest distance from the affected component as an aligned aperture. In embodiments, the dynamic cooling program 108 may select multiple adjustable apertures with the shortest distance from the affected component, for instance five, as aligned apertures. For example, the dynamic cooling program 108 may select the top five closest adjustable apertures as aligned apertures. In embodiments of the invention, the dynamic cooling program 108 may identify the one or more adjustable apertures directly adjacent to the aligned apertures, or adjacent apertures. An adjustable aperture may be adjacent to an aligned aperture if it is within a predetermined threshold distance, such as five centimeters. The threshold distance may be pre-provided.

At 310, the dynamic cooling program 108 may calculate one or more percentage open values for the one or more adjustable apertures and/or the aligned apertures based on the environmental data and/or the component data. Here, the dynamic cooling program 108 determines whether the adjustable apertures should be shut, or whether they should be opened, and how wide the adjustable apertures must be opened, enumerated as a percentage open value. The percentage open value may correspond to the percentage of the adjustable aperture that should not be occluded by the cover, so as to let a corresponding percentage of the airflow through. For example, a percentage open value of 100% may represent the fully open state of the adjustable aperture, where a percentage open value of 0% represents a fully closed state, and a percentage open value of 50% represents a state where the cover has blocked half of the adjustable aperture.

In embodiments, for example where the dynamic cooling program 108 has selected one or more aligned apertures, the dynamic cooling program 108 may determine that all aligned apertures be opened to their fullest extent, to maximize airflow to the affected components. In embodiments, for example where the dynamic cooling program 108 has identified one or more adjacent apertures, the dynamic cooling program 108 may determine that the adjacent apertures be opened to a lesser extent than fully open, in order to ensure that more cool air is directed towards the components that are in current need of the cooler air. For example, where the aligned apertures are set to 100% open, the adjacent apertures may be set to 75% open.

In embodiments, for example where the dynamic cooling program 108 has created an airflow gradient and/or thermal gradient based on pressure or temperature information, the dynamic cooling program 108 may calculate a percentage open value for each adjustable aperture. The dynamic cooling program 108 may calculate the percentage open value for each adjustable aperture based on the airflow gradient and/or the thermal gradient; the dynamic cooling program 108 may average out the temperature values comprising the thermal gradient or the pressure values comprising the airflow gradient to find the average of the temperature or pressure values recorded at the adjustable apertures, and calculate a percentage open value so as to reduce airflow through adjustable apertures where the temperature or pressure was recorded as above the average, and to increase airflow through adjustable apertures where temperature or pressure was recorded as below the average. Adjustable apertures with temperatures falling within a threshold margin of error may remain unchanged. In embodiments, the dynamic cooling program 108 may exempt aligned apertures from consideration with respect to the gradient, as the aligned apertures will be set to the open state. In embodiments, for example where fully opening aligned apertures of a component fails to cool the component below the temperature threshold, the dynamic cooling program 108 may interact with the air-cooling system 146 to request an increase in airflow in or around computing system 202.

In embodiments of the invention, the dynamic cooling program 108 may utilize a machine learning model to improve the calculation of percent open values for the adjustable apertures. The machine learning model may be trained on environmental sensor data to model the relationship between the temperature or pressure measured at the adjustable aperture and the percent open value of the adjustable aperture, either individually or as part of an array or grid of multiple adjustable apertures. In embodiments, the machine learning model may be trained to model the relationship between the workload or power consumption of a component and the percent open value of the aligned apertures and/or adjacent apertures associated with that component. Once trained, the dynamic cooling program 108 may calculate the one or more percentage open values of the adjustable apertures by providing the adjustable aperture, the average temperature or pressure of the gradient, and the temperature or pressure measured at that adjustable aperture to the machine learning model and receiving the percent open value as output. The dynamic cooling program 108 may calculate the one or more percentage open values of the adjacent apertures by providing the associated affected component and its workload to the machine learning model and receiving the percent open value as output.

In some embodiments of the invention, for example where one or more components of the computer system 202 belong to a class of components with a low electromagnetic compatibility, and the environmental sensors 206 comprise at least one electromagnetic interference sensor such as a radio frequency meter, the dynamic cooling program 108 may calculate the percent open value based on the electromagnetic interference. The higher the electromagnetic interference reading, the smaller the open value of the aperture needs to be. The dynamic cooling program 108 may, responsive to determining that an electromagnetic interference reading exceeds a safe electromagnetic threshold, where the safe electromagnetic threshold represents the electromagnetic interference value above which the sensitive component could malfunction, the dynamic cooling program 108 may determine that the current percentage open state of the adjustable aperture be reduced. The electromagnetic threshold may be pre-provided to the dynamic cooling program 108. Because higher workload states are more prone to errors induced by high EMI readings, calculating the percent open value may further be based on a workload currently assigned to the component; the higher the workload of the component, the more sensitive that component is to electromagnetic interference, and therefore the smaller the aperture must be, and conversely the lower the workload of the component, the less sensitive that component is to electromagnetic interference, and the aperture need not be as small. As such, the dynamic cooling program 108 may dynamically update the electromagnetic compatibility of sensitive components based on their workload, so as to reflect the decrease in electromagnetic compatibility as workload increases, and the increase in electromagnetic capability as workload decreases. In embodiments, calculating the percentage open value for a sensitive component may be additionally based on electromagnetic compatibility of a sensitive component and/or electromagnetic interference readings. Furthermore, in embodiments where the enclosure and/or the covers are electromagnetically shielded, the dynamic cooling program 108 may modify any percentage open value calculated based on electromagnetic compatibility to reflect the improved protection from electromagnetic interference, for example by increasing the percent open value.

In some embodiments of the invention, for example where the environmental sensors 206 comprise a camera or proximity sensor, the dynamic cooling program 108 may calculate the percentage open values based on whether a human has been detected through data gathered by the camera or proximity sensor. The dynamic cooling program 108 may analyze the data from the camera or proximity sensor to identify the presence of human personnel, for example through image processing techniques or the presence of movement. If a human is detected, the dynamic cooling program 108 may reduce the percentage open values of the adjustable apertures of the dynamic barrier system 148 to dampen the sound produced by the components of computer system 202 within the enclosure. In embodiments, for example where the environmental sensors 206 comprise a microphone disposed outside the enclosure, the dynamic cooling program 108 may compare the sound volume recorded by the microphone against a sound threshold, where the sound threshold is a volume value above which a sound becomes unsafe or distressing for human personnel. The sound threshold may be provided, for example, as acoustic safety requirements promulgated by a government or private authority. If the sound volume recorded by the microphone exceeds the sound threshold, the dynamic cooling program 108 may continually decrease the percentage open values of the adjustable apertures until the recorded volume has fallen below the sound threshold. Once the dynamic cooling program 108 has determined that no human is present based on the environmental sensor data, the dynamic cooling program 108 may open the covers to the percentage open value that they were at before the human was detected.

In some embodiments of the invention, for example where the component sensors 204 and/or the environmental sensors 206 comprise a temperature sensor, the dynamic cooling program 108 may compare temperature readings from the temperature sensor against a fire emergency threshold, which may be a temperature value that, if exceeded, may indicate the presence of a fire at the location of the sensor that recorded the reading. If the dynamic cooling program 108 determines that the temperature reading exceeds the fire emergency threshold, the dynamic cooling program 108 may set every adjustable aperture to move to a closed state.

At 312, the dynamic cooling program 108 may set the one or more adjustable apertures and/or the one or more adjacent adjustable apertures to the calculated percentage open values. Once the dynamic cooling program 108 has calculated percentage open values for every adjustable aperture of the dynamic barrier system, the dynamic cooling program 108 may execute the process of mechanically opening or closing the covers over the adjustable apertures to transition to the calculated percentage open values. The dynamic cooling program 108 may transmit electronic signals over the WAN 102 to the motors comprising the adjustable apertures to move the covers to the calculated positions. In embodiments, the dynamic cooling program 108 may set the adjustable apertures after calculating percent open values for less than all adjustable apertures.

Referring now to FIG. 4, an exemplary embodiment 400 of a dynamic barrier system 146 is depicted. Here, an enclosure 402 is shown, which is a physical structure designed to hold components of the computing system 202 and protect them from damage. The dynamic barrier system 146 here comprises two static barriers 404, which comprise doors set into the front face of the enclosure 402; the static barriers 404 each comprise a number of adjustable apertures 406 forming a grid, which are a grid of openings in the static barriers 404 equipped with covers each of which may be independently operated by dynamic cooling program 108 to adjust the percentage by which the adjustable apertures 406 are obstructed by the covers, and thereby adjust the possible airflow through the openings. Set into the floor in front of the static barriers 404 are two vents 408, through which the air-cooling system 146 blows air to cool computer system 202.

Environmental sensors 206 are here depicted attached to the exterior surface of the enclosure 402, but one skilled in the art would understand embodiments of the invention to encompass any number or arrangement of environmental sensors 206, both inside and outside enclosure 402. In embodiments, the environmental sensors 206 may include cameras or proximity sensors capable of detecting human presence deployed outside of the enclosure 402; these cameras or proximity sensors may be used to identify the presence of human users within a threshold distance of the enclosure 402, such that dynamic cooling program 108 may operate the adjustable apertures 406 to close and dampen sound produced by the computing system. In embodiments, a temperature sensor and/or pressure sensor may be deployed in every adjustable aperture 406 to enable accurate measurement of temperature and/or pressure at each adjustable aperture 406, such that dynamic cooling program 108 may control the adjustable apertures 406 to direct airflow through the computing system 202. In embodiments, for example where the computing system 202 comprises sensitive electronic equipment that is vulnerable to electromagnetic interference, the environmental sensors 206 may include electromagnetic sensors capable of measuring electromagnetic interference in the environment around the enclosure 402, enabling dynamic cooling program 108 to adjust the width of the adjustable apertures 406 to limit the amount of electromagnetic interference entering or exiting the enclosure 402 based on the requirements of the sensitive electronic equipment. In some embodiments, the static barrier 404 may not contain any environmental sensors 206 and instead, pressure and/or temperature sensors may be deployed close to the static barriers on the exterior and/or interior of the enclosure 402.

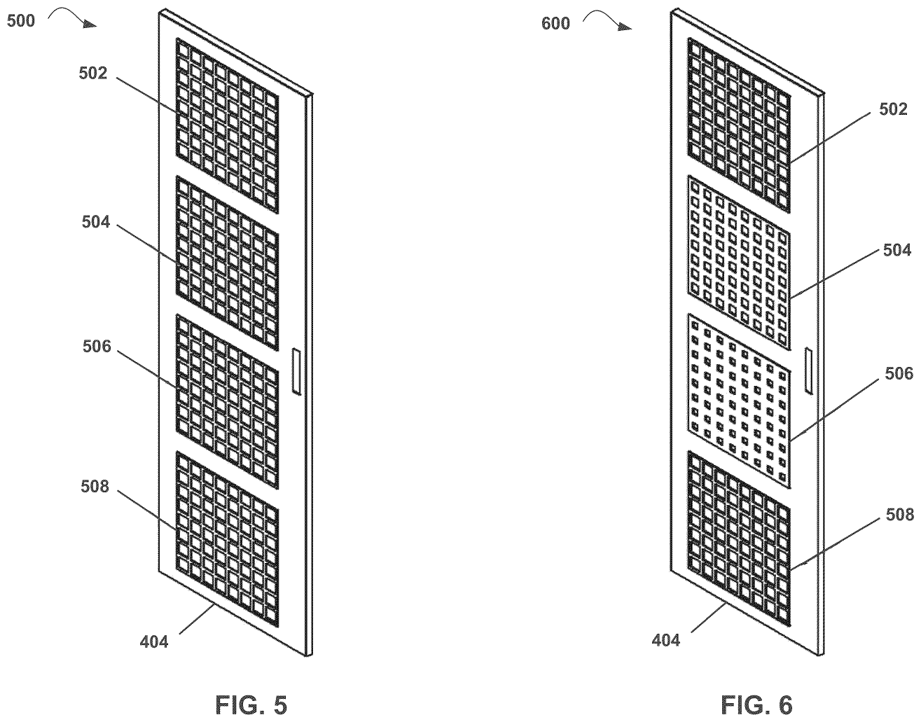

Referring now to FIG. 5, an exemplary default state 500 of the dynamic barrier system 146 is depicted, according to at least one embodiment. Here, a static barrier 404 is shown, equipped with four arrays of adjustable apertures 406; a first array 502, a second array 504, a third array 506, and a fourth array 508. When dynamic cooling program 108 has just been initialized, the dynamic cooling program 108 may set the dynamic barrier system 146 to its default state; in its default state, the dynamic barrier system 146 sets every adjustable aperture 406 to be 100% open, allowing maximum airflow into and out of an enclosure 402. As such, first array 502, second array 504, third array 506, and fourth array 508 are all open to the maximum extent possible.

Referring now to FIG. 6, an exemplary default state 600 of the dynamic barrier system 146 is depicted, according to at least one embodiment. Here, a static barrier 404 is shown, equipped with four arrays of adjustable apertures 406; a first array 502, a second array 504, a third array 506, and a fourth array 508. Once dynamic cooling program 108 has calculated percentage open values for each adjustable aperture 406, the dynamic cooling program 108 may set the dynamic barrier system 146 to a new state, whereby the adjustable apertures 406 are opened to the percentage calculated based on the component data, and the environmental data. Here, the arrays of adjustable apertures 406 are all opened to differing extents based on the calculated percentage open values; first array 502 is opened 100%, second array 504 is opened 50%, third array 506 is opened 25%, and fourth array 508 is opened 100%.

It may be appreciated that FIGS. 2-6 provide only illustrations of individual implementations and do not imply any limitations with regard to how different embodiments may be implemented. Many modifications to the depicted environments may be made based on design and implementation requirements.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method for dynamically cooling and protecting components of a computing system using a dynamic barrier system, the method comprising:
extracting a physical configuration of the computing system and the dynamic barrier system;
monitoring, in real time, component data of one or more components comprising the computing system;
recording, by one or more sensors, environmental data of the computing system;
responsive to determining that an affected component of the one or more components has exceeded a temperature threshold, identifying one or more aligned apertures of one or more adjustable apertures based on the physical configuration;
calculating one or more percentage open values for the one or more adjustable apertures and the one or more aligned apertures based on the environmental data and the component data; and
setting the one or more adjustable apertures and the one or more aligned apertures to the calculated one or more percentage open values.

2. The method of claim 1, further comprising:
identifying one or more adjacent apertures to the one or more aligned apertures; and wherein the calculating further comprises calculating percentage open values for the aligned apertures.

3. The method of claim 1, wherein the components comprise at least one electromagnetically sensitive component, and the calculating is based on one or more readings by an electromagnetic interference sensor of the one or more sensors.

4. The method of claim 1, wherein the calculating is based on a temperature gradient or an airflow gradient.

5. The method of claim 1, wherein the calculating further comprises:
responsive to detecting a human, reducing the percentage open values for the one or more adjustable apertures to reduce a produced sound below a sound threshold.

6. The method of claim 1, further comprising:
responsive to determining that a temperature measurement exceeds a fire emergency threshold, closing the adjustable apertures.

7. The method of claim 1, wherein the calculating is performed using a machine learning model.

8. A computer system for dynamically cooling and protecting components of a computing system using a dynamic barrier system, the computer system comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
extracting a physical configuration of the computing system and the dynamic barrier system;
monitoring, in real time, component data of one or more components comprising the computing system;
recording, by one or more sensors, environmental data of the computing system;
responsive to determining that an affected component of the one or more components has exceeded a temperature threshold, identifying one or more aligned apertures of one or more adjustable apertures based on the physical configuration;
calculating one or more percentage open values for the one or more adjustable apertures and the one or more aligned apertures based on the environmental data and the component data; and
setting the one or more adjustable apertures and the one or more aligned apertures to the calculated one or more percentage open values.

9. The computer system of claim 8, further comprising:
identifying one or more adjacent apertures to the one or more aligned apertures; and wherein the calculating further comprises calculating percentage open values for the aligned apertures.

10. The computer system of claim 8, wherein the components comprise at least one electromagnetically sensitive component, and the calculating is based on one or more readings by an electromagnetic interference sensor of the one or more sensors.

11. The computer system of claim 8, wherein the calculating is based on a temperature gradient or an airflow gradient.

12. The computer system of claim 8, wherein the calculating further comprises:
responsive to detecting a human, reducing the percentage open values for the one or more adjustable apertures to reduce a produced sound below a sound threshold.

13. The computer system of claim 8, further comprising: responsive to determining that a temperature measurement exceeds a fire emergency threshold, closing the adjustable apertures.

14. The computer system of claim 8, wherein the calculating is performed using a machine learning model.

15. A computer program product for dynamically cooling and protecting components of a computing system using a dynamic barrier system, the computer program product comprising:
one or more computer-readable tangible storage medium and program instructions stored on at least one of the one or more tangible storage medium, the program instructions executable by a processor to cause the processor to perform a method comprising:
extracting a physical configuration of the computing system and the dynamic barrier system;
monitoring, in real time, component data of one or more components comprising the computing system;
recording, by one or more sensors, environmental data of the computing system;
responsive to determining that an affected component of the one or more components has exceeded a temperature threshold, identifying one or more aligned apertures of one or more adjustable apertures based on the physical configuration;
calculating one or more percentage open values for the one or more adjustable apertures and the one or more aligned apertures based on the environmental data and the component data; and
setting the one or more adjustable apertures and the one or more aligned apertures to the calculated one or more percentage open values.

16. The computer program product of claim 15, further comprising:
identifying one or more adjacent apertures to the one or more aligned apertures; and wherein the calculating further comprises calculating percentage open values for the aligned apertures.

17. The computer program product of claim 15, wherein the components comprise at least one electromagnetically sensitive component, and the calculating is based on one or more readings by an electromagnetic interference sensor of the one or more sensors.

18. The computer program product of claim 15, wherein the calculating is based on a temperature gradient or an airflow gradient.

19. The computer program product of claim 15, wherein the calculating further comprises:
responsive to detecting a human, reducing the percentage open values for the one or more adjustable apertures to reduce a produced sound below a sound threshold.

20. The computer program product of claim 15, further comprising:
responsive to determining that a temperature measurement exceeds a fire emergency threshold, closing the adjustable apertures.
